(19) United States
(12) Patent Application Publication
(10) Pub. No.: US 2026/0156758 A1
(43) Pub. Date: Jun. 4, 2026

(54) PRESSING APPARATUS, METHOD OF MANUFACTURING DISPLAY DEVICE, AND ELECTRONIC DEVICE

(71) Applicant: SAMSUNG DISPLAY CO., LTD., YONGIN-SI (KR)

(72) Inventors: Sang Wook BAEK, Yongin-si (KR); Jong Hoon PARK, Yongin-si (KR); Ji Hun CHA, Yongin-si (KR); Myung Gil CHOI, Yongin-si (KR)

(21) Appl. No.: 19/283,454

(22) Filed: Jul. 29, 2025

(30) Foreign Application Priority Data
Dec. 2, 2024 (KR) 10-2024-0176880

(51) Int. Cl. H05K 3/40; H10K 59/12; H10K 71/50

(52) U.S. Cl. CPC H05K 3/4007; H10K 59/1201; H10K 71/50; H05K 2203/0195

(57) ABSTRACT

A pressing apparatus includes a support bracket movable in at least one of a first direction and a second direction intersecting the first direction. A first housing is slidable in the second direction. A first driving unit provides a driving force to the first housing. A second housing is disposed on an inner side of the first housing and is slidable in a third direction intersecting the first direction and the second direction. A second driving unit provides a driving force to the second housing. A third driving unit generates a rotational force rotating about the third direction. A compression head is rotatable by the rotational force of the third driving unit. The second driving unit and the third driving unit are aligned on an imaginary line extending in the third direction.

### CROSS-REFERENCE TO RELATED APPLICATION

This application claims priority under 35 U.S.C. § 119 to Korean Patent Application No. 10-2024-0176880, filed on Dec. 2, 2024 in the Korean Intellectual Property Office, the disclosure of which is incorporated by reference in its entirety herein.

### 1. Technical Field

Embodiments of the present disclosure relate to a pressing apparatus, a method of manufacturing a display device, and an electronic device.

### 2. Discussion of Related Art

A display device is an electronic device that displays images and serves as a connection medium between a user and information. The importance of display devices has increased along with the advancement of the information society. Accordingly, the use of display devices, such as liquid crystal display devices and organic light emitting display devices is increasing.

Such display devices may include a display panel that displays an image and a flexible circuit board that provides an electrical signal to the display panel. A method of interposing an anisotropic conductive film between the display panel and the flexible circuit board, and pressing the flexible circuit board against the display panel has been developed to connect the flexible circuit board to the display panel. However, the pressing of the flexible circuit board against the display panel may be inaccurate and lead to malfunctions.

### SUMMARY

An object of the present disclosure is to provide a pressing apparatus that can increase the pressing accuracy of a compression head, a method of manufacturing a display device, and an electronic device.

However, the subject matter of embodiments of the present disclosure is not necessarily limited to the above, and other technical subject matter not mentioned will be clearly understood by those skilled in the art from the following description.

According to an embodiment of the present disclosure, a pressing apparatus includes a support bracket movable in at least one of a first direction and a second direction intersecting the first direction. A first housing is disposed on an inner side of the support bracket. The first housing is slidable in the second direction. A first driving unit is disposed in the support bracket. The first driving unit provides a driving force to the first housing. A second housing is disposed on an inner side of the first housing. The second housing is slidable in a third direction intersecting the first direction and the second direction. A second driving unit is disposed in the first housing. The second driving unit provides a driving force to the second housing. A third driving unit is disposed in the second housing. The third driving unit generates a rotational force rotating about the third direction. A compression head is disposed in the third driving unit. The compression head is rotatable by the rotational force of the third driving unit. The second driving unit and the third driving unit are aligned on an imaginary line extending in the third direction.

In an embodiment, the first driving unit may include a first driving shaft coupled to the first housing by a ball screw, the second driving unit may include a second driving shaft coupled to the second housing by a ball screw, the third driving unit may include a third driving shaft coupled to the compression head, and the second driving shaft and the third driving shaft may be aligned on the imaginary line.

In an embodiment, the first driving unit may be a servo motor.

In an embodiment, the second driving unit may be a servo motor.

In an embodiment, the third driving unit may be a servo motor.

In an embodiment, the pressing apparatus may further include a first guide member disposed between the support bracket and the first housing. The first guide member guiding a sliding of the first housing in the second direction.

In an embodiment, the first guide member may include a 1_1 guide member and a 1_2 guide member located to be symmetrical to each other in the first direction with respect to the imaginary line, and a 1_3 guide member and a 1_4 guide member spaced apart from the 1_1 guide member and the 1_2 guide member in the third direction, respectively, and located to be symmetrical to each other in the first direction with respect to the imaginary line.

In an embodiment, the first guide member may be a cross roller guide.

In an embodiment, the first guide member may limit the first housing from moving in the first direction and the third direction.

In an embodiment, the pressing apparatus may further include a second guide member disposed between the first housing and the second housing. The second guide member guiding a sliding of the second housing in the third direction.

In an embodiment, the second guide member further include a 2_1 guide member and a 2_2 guide member located to be symmetrical to each other in the second direction with respect to the imaginary line.

In an embodiment, the second guide member may be an LM guide.

In an embodiment, the second guide member may limit the second housing from moving in the first direction and the second direction.

In an embodiment, when the first housing slide in the second direction, the second driving unit and the third driving unit may remain aligned on the imaginary line.

According to an embodiment of the present disclosure, a method of manufacturing a memory device includes forming pads in a non-display area on a substrate. The pads and a circuit board having a driver integrated circuit installed thereon are electrically connected to each other. The electrically connecting of the pads and the circuit board includes pressurizing a contact point between the circuit board and the pads using a pressing apparatus. The pressing apparatus includes a support bracket movable in at least one of a first direction and a second direction intersecting the first direction. A first housing is disposed on an inner side of the support bracket. The first housing is slidable in the second direction. A first driving unit is disposed in the support bracket. The first driving unit provides a driving force to the first housing. A second housing is disposed on an inner side of the first housing. The second housing is slidable in a third direction intersecting the first direction and the second direction. A second driving unit is disposed in the support bracket. The second driving unit provides a driving force to the second housing. A third driving unit is disposed in the support bracket. The third driving unit generate a rotational force rotating about the third direction. A compression head is rotatable by the rotational force of the third driving unit. The second driving unit and the third driving unit are aligned on an imaginary line extending in the third direction.

According to an embodiment of the present disclosure, an electronic device includes a processor, pixels, and a display device displaying an image in the pixels in response to control signals from the processor. The display device is manufactured according to the previously stated manufacturing method.

### BRIEF DESCRIPTION OF THE DRAWINGS

FIG. 1 is a perspective view illustrating a pressing apparatus according to an embodiment of the present disclosure.

FIG. 2 is a front view illustrating some components of the pressing apparatus shown in FIG. 1 according to an embodiment of the present disclosure.

FIG. 3 is a side view illustrating some components of the pressing apparatus shown in FIG. 1 according to an embodiment of the present disclosure.

FIG. 4 is a plan view illustrating a display device according to an embodiment of the present disclosure.

FIG. 5 is a plan view illustrating a sub-pixel according to an embodiment of the present disclosure.

FIG. 6 is a cross-sectional view cut along line I-I′ of FIG. 5 according to an embodiment of the present disclosure.

FIG. 7 is a flowchart illustrating a method of manufacturing a display device according to an embodiment of the present disclosure.

FIG. 8 is a block diagram illustrating an electronic device including the display device of FIG. 9 according to an embodiment of the present disclosure.

FIG. 9 is a perspective view illustrating an example of a smartphone that can be implemented using the electronic device of FIG. 8 according to an embodiment of the present disclosure.

FIG. 10 is a perspective view illustrating an example of a tablet computer that can be implemented using the electronic device of FIG. 8 according to an embodiment of the present disclosure.

### DETAILED DESCRIPTION OF EMBODIMENTS

Hereinafter, non-limiting embodiments of the present disclosure will be described in more detail with reference to the accompanying drawings. In the description below, only a necessary part to understand an operation according to the present disclosure is described and the descriptions of other parts may be omitted to avoid unnecessarily obscuring the subject matter of the present disclosure. In addition, the present disclosure is not limited to the described embodiments, but may be embodied in various different forms.

In the entire specification, when an element is referred to as being “connected” or “coupled” to another element, it can be directly connected or coupled to another element or be indirectly connected or coupled to another element with one or more intervening elements interposed therebetween. When an element is referred to as being “directly connected” or “directly coupled” to another element, no intervening elements may be present. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of this disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. For example, the term “above,” may encompass both an orientation of above and below. The apparatus may be otherwise oriented (e.g., rotated 90 degrees or at other orientations) and the spatially relative descriptors used herein interpreted accordingly.

Various non-limiting embodiments are described with reference to the figures schematizing such embodiments. It will thus be envisaged that the shapes may vary, for example depending on tolerances and/or manufacturing techniques. Accordingly, the described embodiments are not necessarily to be construed as limited to the particular shapes shown, but rather as including changes in shapes that occur, for example, as a result of fabrication. As such, the shapes shown in the figures may not show actual shapes of areas of the apparatus, and embodiments are not necessarily limited thereto.

The present disclosure concerns a pressing apparatus having a compression head which pressurizes a contact point between a circuit board and pads of a display device to electrically connect the pads and the circuit board to each other. The pressing apparatus includes a second driving shaft of a second driving unit and a third driving shaft of a third driving unit that are aligned with each other on an alignment axis extending in a vertical direction.

Due to the alignment of the second and third driving shafts about the alignment axis, a torque that is applied to the third driving shaft is reduced and creep-fatigue deformation may be prevented. Therefore, the compression accuracy of the compression head may be increased.

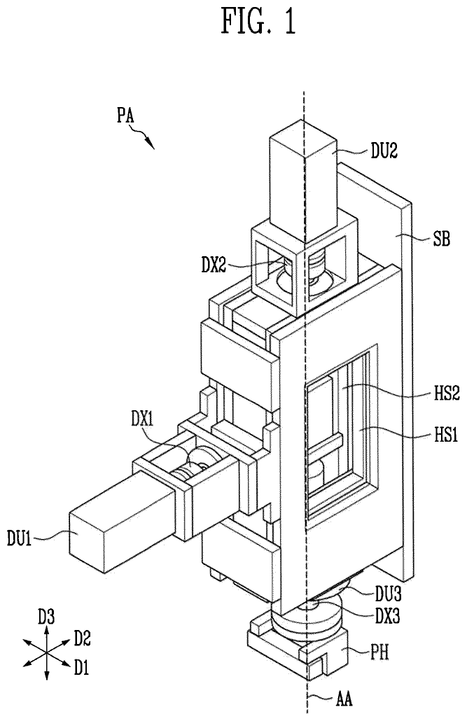

Hereinafter, a pressing apparatus PA will be described with reference to FIGS. 1 to 3.

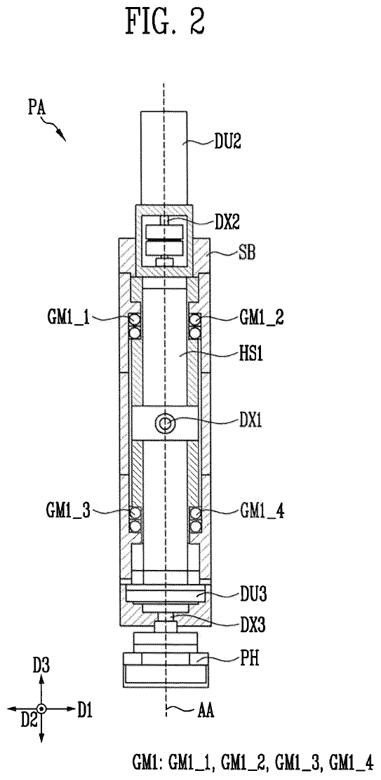

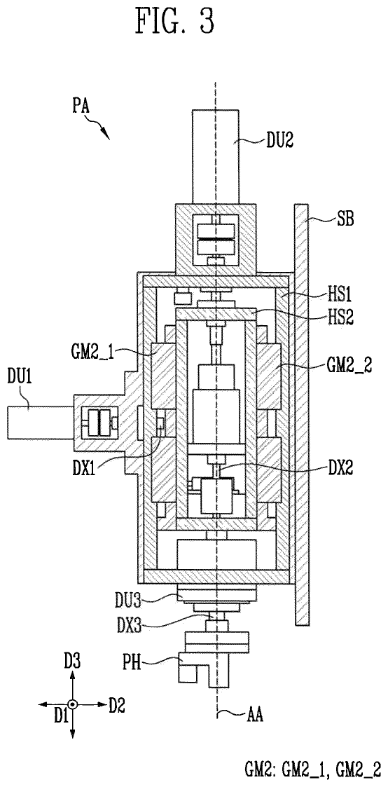

FIG. 1 is a perspective view of a pressing apparatus PA according to an embodiment. FIG. 2 is a front view illustrating some of the components of the pressing apparatus PA shown in FIG. 1. FIG. 3 is a side view illustrating some of the components of the pressing apparatus PA shown in FIG. 1.

Referring to FIGS. 1 to 3, in an embodiment the pressing apparatus PA may include a support bracket SB, a first housing HS1, a first driving unit DU1, a second housing HS2, a second driving unit DU2, a third driving unit DU3, and a compression head CH.

The support bracket SB may be a frame in which the other components of the pressing apparatus PA are fixed or slidable. The support bracket SM may be configured to be movable in a first direction D1 on its own. For example, in an embodiment the support bracket SB may be installed (e.g., disposed) in an automated device that may be driven on a cartesian coordinate, such as a gantry robot, and may be installed (e.g., disposed) so as to be slidable in at least one of the first direction D1 and a second direction D2 intersecting the first direction D1 on a plane formed by the first and second directions D1 and D2.

In an embodiment, the first housing HS1 may support other components of the pressing apparatus PA other than the support bracket SB so as to be movable in the second direction D2. In an embodiment, the first housing HS1 may be installed (e.g., disposed) on an inner side of the support bracket SB so as to be slidable in the second direction D2. Since the first housing HS1 is installed (e.g., disposed) on the support bracket SB, when the support bracket SB moves, the first housing HS1 may move in at least one of the first direction D1 and the second direction D2 together with the support bracket SB.

The first driving unit DU1 may be installed (e.g., disposed) on the support bracket SB to provide a driving force for the first housing HS1 to slide in the second direction D2. In some embodiments, the first driving unit DU1 may be a servo motor and may include a first driving shaft DX1 coupled to the first housing HS1 by a ball screw. In an embodiment, according to the configuration above, the driving force of the first driving unit DU1 may be implemented by rotation of the first driving shaft DX1, and the first housing HS1 may move linearly in the second direction D2 in an empty space provided on the inner side of the support bracket SB according to the rotation of the first driving shaft DX1.

In an embodiment, the second housing HS2 may be installed (e.g. disposed) on an inner side of the first housing HS1 and may be slidable in a third direction D3 intersecting the first direction D1 and the second direction D2. As described above, the second housing HS2 is installed (e.g., disposed) in the first housing HS1, so when the first housing HS1 moves, the second housing HS2 may move in the second direction D2 together with the first housing HS1. In addition, the second housing HS2 may move in at least one of the first direction D1 and the second direction D2 together with the support bracket SB when the support bracket Sb moves.

In an embodiment, the second driving unit DU2 may be installed in the first housing HS1 to provide a driving force for the second housing HS2 to slide in the third direction D3. In some embodiments, the second driving unit DU2 may be a servo motor like the first driving unit DU1, and may include a second driving shaft DX2 coupled to the second housing HS2 by a ball screw. In an embodiment, according to the configuration above, the driving force of the second driving unit DU2 may be implemented by rotation of the second driving shaft DX2, and the second housing HS2 may move linearly in the third direction D3 in an empty space provided on the inner side of the first housing HS1 according to the rotation of the second driving shaft DX2.

In an embodiment, the third driving unit DU3 may be installed in the second housing HS2 to generate a rotational force rotating about the third direction D3. In some embodiments, the third driving unit DU3 may be a servo motor like the first driving unit DU1 and the second driving unit DU2. Since the third driving unit DU3 is installed in the second housing HS2, when the second housing HS2 moves, the third driving unit D2 may move in the third direction D3 together with the second housing HS3. In addition, the third driving unit DU3 may move in the second direction D2 together with the first housing HS1 when the first housing HS2 moves. In addition, when the support bracket SB moves, the third driving unit DU3 may move in at least one of the first direction D1 and the second direction D2 together with the support bracket SB.

A compression head PH may be installed in the third driving unit DU3 and may be rotatable by the rotational force of the third driving unit DU3. The third driving unit DU3 may include a third driving shaft DX3 coupled to the compression head PH. In an embodiment, according to the configuration above, the rotational force of the third driving unit DU3 may be implemented by rotation of the third driving shaft DX3, and the compression head PH may rotate about the third direction D3 according to the rotation of the third driving shaft DX3.

In some embodiments, the second driving unit DU2 and the third driving unit DU3 may be aligned on an imaginary line AA (hereinafter referred to as an “alignment axis”) extending in the third direction D3. For example, the second driving shaft DX2 and the third driving shaft DX3 may be aligned on the alignment axis AA. In an embodiment, when the first housing HS1 slides in the second direction D2 by the driving of the first driving unit DU1, the second driving shaft DX2 and the third driving shaft DX3 may maintain an aligned state on the alignment shaft AA.

In a comparative embodiment, when the second driving shaft DX2, which is the rotational center of the second driving unit DU2, and the third driving shaft DX3, which is the rotation center of the third driving unit DU3, are not aligned with the alignment axis AA and the pressing apparatus PA is driven eccentrically for a long time, a creep-fatigue deformation may occur due to the accumulation of torque applied to the third driving shaft DX3, which may reduce the compression accuracy of the compression head PH. In contrast, in the pressing apparatus PA according to an embodiment of the present disclosure, since the second driving shaft DX2 and the third driving shaft DX3 are aligned on the alignment axis AA, even when the pressing apparatus PA is driven for a long time, the torque that may be applied to the third driving shaft DX3 is minimized due to the eccentricity of the second driving shaft DX2 and third driving shaft DX3, and as a result, the compression accuracy of the compression head PH that rotates around the third driving shaft DX3 may be increased.

In an embodiment, the pressing apparatus PA may further include a first guide member GM1 and a second guide member GM2.

Referring to FIG. 2, in an embodiment the first guide member GM1 is installed between the support bracket SB and the first housing HS1, so as to guide sliding of the first housing HS1 in the second direction D2. In some embodiments, the first guide member GM1 may be a cross roller guide, but is not necessarily limited thereto. For example, the first guide member GM1 may be any component capable of preventing wear and/or breakage of the support bracket SB and/or the first housing HS1 by removing or at least minimizing mutual friction when the first housing HS2 slides in the inner side of the support bracket SB.

In an embodiment, the first guide member GM1 may include a 1_1 guide member GM1_1 and a 1_2 guide member GM1_2 located to be symmetrical to each other in the first direction D1 with respect to the alignment axis AA, and a 1_3 guide member GM1_3 and a 1_4 guide member GM1_4 spaced apart from the 1_1 guide member GM1_1 and the 1_2 guide member GM1_2 in the third direction D3, respectively, and symmetrical to each other in the first direction D1 with respect to the alignment axis AA. In an embodiment, the first guide member GM1 may guide the first housing HS1 to slide in the second direction D2 while limiting (e.g., restricting) the first housing HS2 from moving in the first direction D1 and the third direction D3.

Referring to FIG. 3, in an embodiment the second guide member GM2 may be installed between the first housing HS1 and the second housing HS2 to guide sliding of the second housing HS1 in the third direction D3. In some embodiments, the second guide member GM2 may be an LM guide (e.g., a linear motion guide), but is not necessarily limited thereto. For example, the second guide member GM2 may be any component capable of preventing wear and/or breakage of the first housing HS1 and/or the second housing HS2 by removing or at least minimizing mutual friction when the second housing HS1 slides in the inner side of the first housing HS2.

In an embodiment, the second guide member GM2 may include a 2_1 guide member GM2_1 and a 2_2 guide member GM2_2 located to be symmetrical to each other in the second direction D2 with respect to the alignment axis AA. In an embodiment, the second guide member GM2 may guide the second housing HS2 to slide in the third direction D3 while limiting (e.g., restricting) the second housing HS1 from moving in the first direction D1 and the second direction D2.

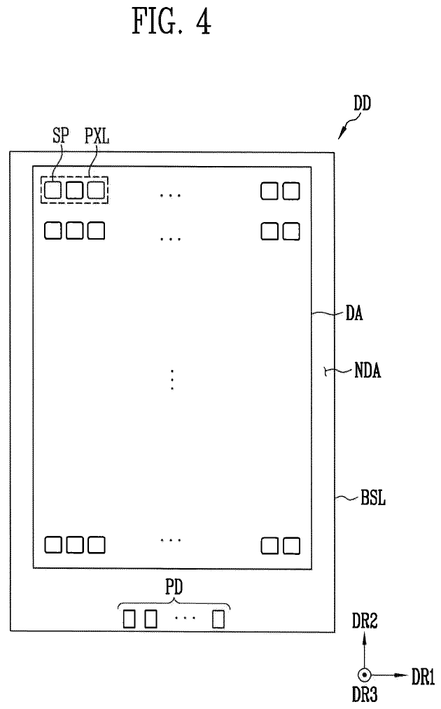

Hereinafter, a display device DD will be described with reference to FIGS. 4 to 6.

FIG. 4 is a plan view illustrating the display device DD according to an embodiment.

The display device DD of FIG. 4 may be manufactured using the above-described pressing apparatus PA.

Referring to FIG. 4, the display device DD (e.g., a display panel) may include a display area DA and a non-display area NDA. The display device DD may display an image through the display area DA. The non-display area NDA may be located around the display area DA (e.g., in a plan view).

In an embodiment, the display device DD may include a substrate SUB, sub-pixels SP, and/or pads PD.

The sub-pixels SP may be located in the display area DA on the substrate SUB. In an embodiment, the sub-pixels SP may be arranged in a matrix form in the first direction DR1 and the second direction DR2 intersecting the first direction DR1, but are not necessarily limited thereto. For example, in some embodiments the sub-pixels SP may be arranged in a zigzag form in the first direction DR1 and the second direction DR2. In other embodiments, the sub-pixels SP may be arranged in a PENTILE™ form. The first direction DR1 may be a row direction, and the second direction DR2 may be a column direction. Two or more of the sub-pixels SP may form a pixel PXL.

A component for controlling the sub-pixels SP may be located in the non-display area NDA on the substrate SUB. For example, wirings connected to the sub-pixels SP, such as gate lines and data lines, may be located in the non-display area NDA.

The pads PD may be located in the non-display area NDA on the substrate SUB. The pads PD may be electrically connected to the sub-pixels SP through the wirings. For example, in an embodiment the pads PD may be connected to the sub-pixels SP through the data lines.

Voltages and signals necessary for the operation of components included in the display device DD may be provided from a driver integrated circuit through the pads PD. For example, the data lines may be connected to (e.g., electrically connected thereto) the driver integrated circuit via the pads PD. In addition, power supply voltages may be received from the driver integrated circuit via the pads PD.

In some embodiments, a conductive adhesive member, such as an anisotropic conductive layer may be used to electrically connect a circuit board to the pads PD. The circuit board may be a flexible circuit board or a flexible layer including a flexible material. In an embodiment, the driver integrated circuit may be mounted on the circuit board and electrically connected to the pads PD. The compression head PH of the pressing apparatus PA may electrically connect the circuit board and the pads PD by pressurizing a contact point between the circuit board and the pads PD.

In some embodiments, the display area DA may have various shapes. The display area DA may have a closed loop shape including straight and/or curved sides (e.g., in a plan view). For example, the display area DA may have shapes, such as a polygon, a circle, a semicircle, and an ellipse (e.g. in a plan view).

In some embodiments, the display device DD may have a flat display surface. Alternatively, the display device DD may have an at least partially round display surface. In addition, in an embodiment the display device DD may be bendable, foldable, rollable or otherwise deformable. In such embodiments, the display device DD and/or the substrate SUB may include materials having a flexible property.

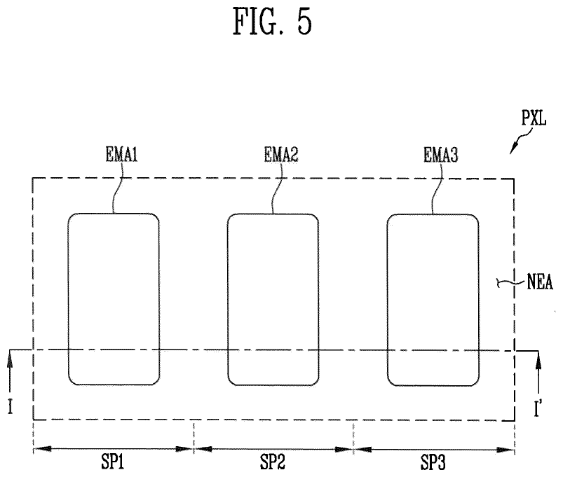

FIG. 5 is a plan view illustrating a sub-pixel according to an embodiment.

Referring to FIG. 5, in an embodiment the pixel PXL may include first to third sub-pixels SP1 to SP3 arranged in the first direction DR1.

The first sub-pixel SP1 may include a first light emitting area EMA1 and a non-light emitting area NEA around the first light emitting area EMA1 (e.g., in a plan view). The second sub-pixel SP2 may include a second light emitting area EMA2 and the non-light emitting area NEA around the second light emitting area EMA2 (e.g., in a plan view). The third sub-pixel SP3 may include a third light emitting area EMA3 and the non-light emitting area NEA around the third light emitting area EMA3 (e.g., in a plan view).

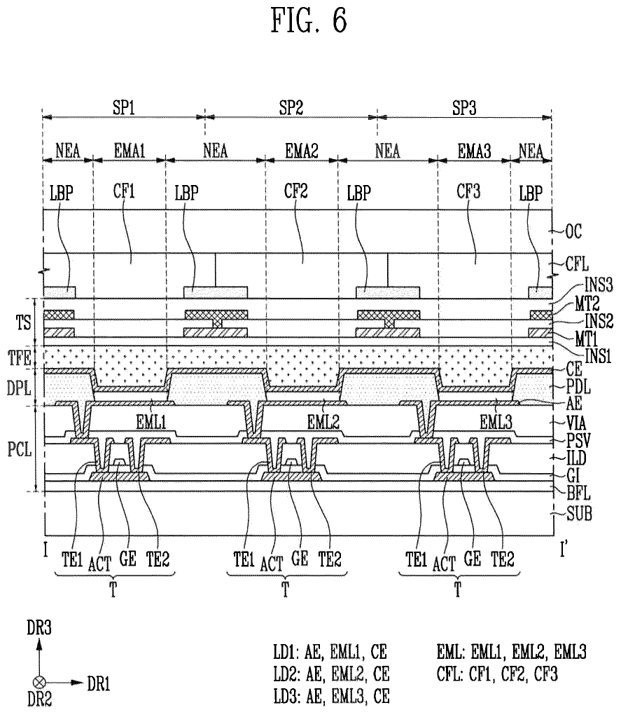

The first light emitting area EMA1 may be a region where light is emitted from a first light emitting layer EML1 (refer to FIG. 6) of the first sub-pixel SP1. The second light emitting region EMA2 may be a region where light is emitted from a second light emitting layer EML2 (refer to FIG. 6) of the second sub-pixel SP2. The third light emitting region EMA3 may be a region where light is emitted from the third light emitting layer EML3 (refer to FIG. 6) of the third sub-pixel SP3.

FIG. 6 is a cross-sectional view cut along line I-I′ of FIG. 5.

Referring to FIG. 6, the first to third sub-pixels SP1 to SP3 may include the light emitting areas EMA1, EMA2, and EMA3, respectively, and the non-light emitting area NEA may be located between the light emitting areas EMA1, EMA2 and EMA3 of the first to third sub-pixels SP1 to SP3 (e.g., in the first direction DR1).

In an embodiment, each of the first to third sub-pixels SP1 to SP3 may include a pixel circuit layer PCL, a display element layer DPL, and/or a thin film encapsulation layer TFE sequentially located on the substrate SUB (e.g., in the third direction DR3).

The substrate SUB may form a base plane. The substrate SUB may include a transparent insulating material to allow transmission of light. The SUB may be a rigid substrate or a flexible substrate. In an embodiment, the rigid substrate may be, for example, one of a glass substrate, a quartz substrate, a glass ceramic substrate, and a crystalline glass substrate. The flexible substrate may be one of a film substrate including a polymeric organic material and a plastic substrate. For example, in an embodiment the flexible substrate may include, but is not necessarily limited to, at least one of polystyrene, polyvinyl alcohol, polymethyl methacrylate, polyethersulfone, polyacrylate, polyetherimide, polyethylene naphtholate, polyethylene terephthalate, polyphenylene sulfide, polyacrylate, polyimide, polycarbonate, triacetate cellulose, cellulose acetate propionate. For example, the substrate SUB may be a substrate including silicon. In some embodiments, the display device DD may be an OLED on Silicon (OLEDoS) display device including a display panel formed on a silicon substrate.

In an embodiment, the pixel circuit layer PCL may include a buffer layer BFL, a gate insulating layer GI, an interlayer insulating layer ILD, a passivation layer PSV, and/or a via layer VIA sequentially stacked on the substrate SUB in the third direction DR3.

The buffer layer BFL may be an inorganic insulating layer including an inorganic material. In an embodiment, the buffer layer BFL may include at least one of metal oxides, such as silicon nitride (SiNx), silicon oxide (SiOx), silicon oxynitride (SiOxNy), and aluminum oxide (AlOx). The buffer layer BFL may be provided as a single layer, but may also be provided as multiple layers of at least a double layer. In an embodiment in which the buffer layer BFL is provided as multiple layers, each layer may include the same material or different materials from each other. However, embodiments of the present disclosure are not necessarily limited thereto and the buffer layer BFL may be omitted depending on the material and process conditions of the substrate SUB.

A transistor T may be located on the buffer layer BFL (e.g., disposed directly thereon in the third direction DR3). In an embodiment, the transistor T may include an active pattern ACT, a gate electrode GE, a first transistor electrode TE1, and/or a second transistor electrode TE2.

The active pattern ACT may be located on the buffer layer BFL (e.g., disposed directly thereon in the third direction DR3). The active pattern ACT may include a polysilicon semiconductor. For example, the active pattern ACT may be formed through a low temperature polysilicon process. However, embodiments of the present disclosure are not necessarily limited thereto, and the active pattern ACT may include an oxide semiconductor, a metal oxide semiconductor, or the like.

The active pattern ACT may include a channel region, a first contact region connected to one end of the channel region, and a second contact region connected to the other end of the channel regions, respectively. The channel region, the first contact region, and the second contact region may include a semiconductor layer that is not doped with impurities or is doped with impurities. In an embodiment, the first contact region and the second contact region may include an impurity-doped semiconductor layer, and the channel region may include a semiconductor layer that is not doped with impurities. As the impurity, for example, a p-type impurity may be used, but is not necessarily limited thereto. One of the first and second contact regions may be a source region and the other may be a drain region.

A gate insulating layer GI may be located on (e.g., disposed directly thereon) the active pattern ACT. The gate insulating layer GI may be an inorganic layer (e.g., an inorganic insulating layer) including an inorganic material. For example, in an embodiment the gate insulating layer GI may include at least one of metal oxides, such as silicon nitride (SiNx), silicon oxide (SiOx), silicon oxynitride (SiOxNy), and aluminum oxide (AlOx). However, the material of the gate insulating layer GI is not necessarily limited to the above-described materials. In some embodiments, the gate insulating layer GI may include an organic layer (e.g., an organic insulating layer) including an organic material. The gate insulating layer GI may be provided as a single layer, but may also be provided as multiple layers of at least a double layer.

The gate electrode GE may be located on the gate insulating layer GI (e.g., disposed directly thereon in the third direction DR3). The gate electrode GE may overlap the channel region of the active pattern ACT (e.g., in the third direction DR3). In an embodiment, the gate electrode GE may form a single layer selected from the group consisting of copper (Cu), molybdenum (Mo), tungsten (W), aluminum neodymium (AlNd), titanium (Ti), aluminum (Al), silver (Ag), and alloys thereof, or a double-layer or multi-layer structure of low-resistance materials, such as molybdenum (Mo), titanium (Ty), copper (Cu) aluminum (Al), or silver (Ag) to reduce wiring resistance.

The interlayer insulating layer ILD may be located on (e.g., disposed directly thereon) the gate electrode GE. The interlayer insulating layer ILD may include the same material as the gate insulating layer GI or may include one or more materials selected from the materials exemplified as constituent materials of the gate insulating layer GI.

The first transistor electrode TE1 and the second transistor electrode TE2 may be located on the interlayer insulating layer ILD (e.g., disposed directly thereon in the third direction DR3).

In an embodiment, the first transistor electrode TE1 may be in direct contact with the first contact region of the active pattern ACT through a contact hole penetrating the interlayer insulating layer ILD and the gate insulating layer GI. In an embodiment in which the first contact region is the source region, the first transistor electrode TE1 may be a first source electrode.

The second transistor electrode TE2 may be in direct contact with the second contact region of the other end of the active pattern ACT through the contact hole penetrating the interlayer insulating layer ILD and the gate insulating layer GI. In an embodiment in which the second contact region is the drain region, the second transistor electrode TE2 may be a second drain electrode.

The first transistor electrode TE1 and the second transistor electrode TE2 may each include the same material as the gate electrode GE or may include one or more materials selected from the materials exemplified as constituent materials of the gate electrode GE.

The passivation layer PSV may be located on (e.g., disposed directly thereon) the first transistor electrode TE1 and the second transistor electrode TE2. The passivation layer PSV (e.g., a protective layer) may be an inorganic layer (e.g., an inorganic insulating layer) including an inorganic material or an organic layer (e.g., an organic insulating layer) including organic material. In an embodiment, the inorganic layer may include, for example, at least one of metal oxides, such as silicon oxide (SiOx), silicon nitride (SiNx), silicon oxynitride (SiOxNy), and aluminum oxide (AlOx). In an embodiment, the organic layer may include, for example, at least one of an acrylic resin, an epoxy resin, a phenolic resin, a polyamide resin, a polyimide resin, an unsaturated polyester resin, a polyphenylene ethers resin, a polyphenylene sulfides resin, and a benzocyclobutene resin.

The via layer VIA may be located on the passivation layer PSV (e.g., disposed directly thereon in the third direction DR3). The via layer VIA may include the same material as the passivation layer PSV or may include one or more materials selected from the materials exemplified as constituent materials of the passivation layers PSV. In some embodiments, the via layer VIA may be an organic layer including an organic material.

The display element layer DPL may be located on the pixel circuit layer PCL (e.g., disposed directly thereon in the third direction DR3). The display element layer DPL may include a light emitting element LD that emits light. The first to third sub-pixels SP1 to SP3 may include first to third light emitting elements LD1 to LD3, respectively.

The first light emitting element LD1 may include an anode electrode AE, the first light emitting layer EML1, and a cathode electrode CE. The second light emitting device LD2 may include the anode electrode AE, the second light emitting layer EML2, and the cathode electrode CE. The third light emitting element LD3 may include the anode electrode AE, the third light emitting layer EML3, and the cathode electrode CE. For example, in an embodiment the first to third light emitting elements LD1 to LD3 may be front-emitting organic light emitting elements.

The anode electrode AE of each of the sub-pixels SP are located in the light emitting areas EMA1, EMA2, and EMA3, and may be spaced apart from each other (e.g., in the first direction DR1). The anode electrode AE of each of the sub-pixels SP may be electrically connected to the first transistor electrode TE1 of each of the sub-pixels SP through the contact hole penetrating the via layer VIA and the passivation layer PSV.

A bank PDL may be located on (e.g., disposed directly thereon) the anode electrode AE. The bank PDL may define (e.g., partition from each other) the light emitting areas EMA1, EMA2, and EMA3 of each of the sub-pixels SP. The bank PDL may include an opening that partially exposes the anode electrode AE of each of the sub-pixels SP. For example, in an embodiment, the bank PDL may cover lateral ends of the anode electrode AE and the opening may expose a central portion of the anode electrode AE.

In an embodiment, the bank PDL may be an organic insulating layer including an organic material. For example, the organic material may include, but are not necessarily limited to, acryl resins, epoxy resins, phenolic resins, polyamide resins, polyimide resins, and the like. For example, the bank PDL may be an inorganic insulating layer including an inorganic material.

In some embodiments, the bank PDL may include a light absorbing material or may absorb light introduced from the outside (e.g., the external environment) by applying a light absorbing agent. For example, in an embodiment the bank PDL may include a carbon-based black pigment. However, embodiments of the present disclosure are not necessarily limited thereto, and the bank PDL may include an opaque metal material, such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni) having a high light absorption rate.

The emitting layer EML of each of the sub-pixels SP may be located on the anode electrode AE exposed by the bank PDL. The cathode electrode CE may be disposed on the emitting layer EML. In an embodiment, the cathode electrode CE may be disposed over all of the first to third sub-pixels SP1 to SP3. In an embodiment, the cathode electrode CE may be provided as a common electrode. However, embodiments of the present disclosure are not necessarily limited thereto.

In an embodiment, the cathode electrode (CE) may include a metal layer, such as silver (Ag), magnesium (Mg), aluminum (Al), platinum (Pt), palladium (Pd), gold (Au), nickel (Ni), neodymium (Nd), iridium (Ir), chromium (Cr), or an alloy thereof, and/or a transparent conductive layer, such as indium tin oxide (ITO), indium zinc oxide (IZO), zinc oxide (ZnO), or indium tin zinc oxide (ITZO). In some embodiments, the cathode electrode CE may include multiple layers, such as a double layer or more including a thin metal layer, for example, a triple layer of ITO/Ag/ITO.

A thin film encapsulation layer TFE may be located on the display element layer DPL (e.g., disposed directly thereon in the third direction DR3). The thin film encapsulation layer TFE may have a single layer structure or a multi-layer structure. The thin film encapsulation layer TFE may include an insulating layer covering the light emitting device LD. The thin film encapsulation layer TFE may include at least one inorganic layer and at least one organic layer. For example, the thin film encapsulation layer TFE may have a structure in which an organic layer and an inorganic layer are alternately stacked (e.g., in the third direction DR3). For example, the thin film encapsulation layer TFE may include a first inorganic layer, an organic layer located on the first inorganic layer, and a second inorganic layer located on the organic layer.

A sensing layer TS may be located on the thin film encapsulation layer TFE (e.g., disposed directly thereon in the third direction DR3). In an embodiment, the sensing layer TS may include a first insulating layer INS1, a first conductive layer MT1, a second insulating layer INS2, a second conductive layer MT2, and/or a third insulating layer INS3.

The first insulating layer INS1 may be located on the thin film encapsulation layer TFE (e.g., disposed directly thereon in the third direction DR3). The first insulating layer INS1 may be an inorganic insulating layer including an inorganic material. In an embodiment, the inorganic insulating layer may include an inorganic insulating material, such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), or zinc oxide (ZnOx). In some embodiments, the first insulating layer INS1 may be omitted or may include the uppermost layer of the thin film encapsulation layer TFE.

The first conductive layer MT1 may be located on the first insulating layer INS1 (e.g., disposed directly thereon in the third direction DR3). The first conductive layer MT1 may be partially opened so as not to overlap the light emitting element LD of each of the sub-pixels SP (e.g., in the third direction DR3). For example, the first conductive layer MT1 may be located to overlap (e.g., in the third direction DR3) the non-light emitting area NEA around the light emitting areas EMA1, EMA2, and EMA3.

The first conductive layer MT1 may include a metal layer or a transparent conductive layer. For example, in an embodiment the metal layer may include molybdenum, titanium, copper, aluminum, and alloys thereof. The transparent conductive layer may include, but is not necessarily limited to, one of indium tin oxide (ITO), indium zinc oxide (IZO), zinc oxide (ZnO), indium tin zinc oxide (ITZO), PEDOT, and metal nanowires. The first conductive layer MT1 may form a connection electrode connecting sensing electrodes.

The second insulating layer INS2 may be located on (e.g., disposed directly thereon) the first conductive layer MT1. The second insulating layer INS2 may include the same material as the first insulating layer INS1, or may include one or more materials selected from materials described as constituent materials of the first insulating layer INS1.

The second conductive layer MT2 may be located on the second insulating layer INS2 (e.g., disposed directly thereon in the third direction DR3). The second conductive layer MT2 may be partially opened so as not to overlap the light emitting element LD of each of the sub-pixels SP (e.g., in the third direction DR3). For example, the second conductive layer MT2 may be located to overlap (e.g., in the third direction DR3) the non-light emitting area NEA around the light emitting areas EMA1, EMA2, and EMA3.

The second conductive layer MT2 may include the same material as the first conductive layer MT1, or may include one or more materials selected from materials exemplified as constituent materials of the first conductive layer MT1.

In an embodiment, the second conductive layer MT2 may be electrically connected to the first conductive layer MT1 through a contact hole penetrating the second insulating layer INS2. The second conductive layer MT2 may form the sensing electrodes.

The third insulating layer INS3 may be located on (e.g., disposed directly thereon) the second conductive layer MT2. The third insulating layer INS3 may be an organic insulating layer including an organic material, but is not necessarily limited thereto. For example, the third insulating layer INS3 may include an inorganic layer or may have a structure in which an organic layer and an inorganic layer are alternately stacked (e.g., in the third direction DR3).

A light blocking layer LBP may be located on the display element layer DPL, the thin film encapsulation layer TFE, and/or the sensing layer TS. For example, as shown in an embodiment of FIG. 6, the light blocking layer LBP may be disposed on the third insulating layer INS3 of the sensing layer TS (e.g., disposed directly thereon in the third direction DR3). The light blocking layer LBP may include an opening overlapping the light emitting element LD (e.g., in the third direction DR3). For example, the light blocking layer LBP may be located to overlap (e.g., in the third direction DR3) the non-light-emitting area NEA around the light-emitting areas EMA1, EMA2, and EMA.

The light blocking layer LBP may include a light shielding material to prevent light leakage and color mixing defects. In an embodiment, the light blocking layer LBP may include, but is not necessarily limited to, a black matrix. In some embodiments, the light blocking layer LBP may include carbon black (CB) and/or titanium black (TiBK).

A color filter layer CFL may be located on (e.g., disposed directly thereon) the light blocking layer LBP. In an embodiment, the color filter layer CFL may include first to third color filters CF1 to CF3 that match the color of each of the sub-pixels SP. A full-color image may be displayed by arranging the first to third color filters CF1 to CF3, each of which is disposed in one of the first to third sub-pixels SP1 to SP3.

In an embodiment, the color filter layer CFL may include the first color filter CF1 located in the first sub-pixel SP1 to selectively transmit light emitted from the first sub-pixel SP1, the second color filter CF2 located in the second sub-pixel SP2 to selectively transmit light emitted from the second sub-pixel SP2, and the third color filter CF3 located in the third sub-pixel SP3 to selectively transmit light emitted from the third sub-pixel SP3.

In some embodiments, the first color filter CF1, the second color filter CF2, and the third color filter CF3 may be a red color filter, a green color filter, and a blue color filter, respectively, but are not necessarily limited thereto.

The first color filter CF1 may include a color filter material that selectively transmits light of the first color (e.g., red). For example, in an embodiment in which the first sub-pixel SP1 is a red sub-pixel, the first color filter CF1 may include a red color filter material.

The second color filter CF2 may include a color filter material that selectively transmits light of a second color (e.g., green). For example, in an embodiment in which the second sub-pixel SP2 is a green sub-pixel, the second color filter CF2 may include a green color filter material.

The third color filter CF3 may include a color filter material that selectively transmits light of a third color (e.g., blue). For example, in an embodiment in which the third sub-pixel SP3 is a blue sub-pixel, the third color filter CF3 may include a blue color filter material.

An overcoat layer OC may be provided on the color filter layer CFL (e.g., disposed directly thereon in the third direction DR3). The overcoat layer OC may include a variety of materials suitable for protecting the bottom layers from foreign materials, such as dust, moisture, or the like. In some embodiments, the overcoat layer OC may include at least one of an inorganic insulating layer and an organic insulating layer. For example, the overcoat layer OC may include epoxy, but is not necessarily limited thereto.

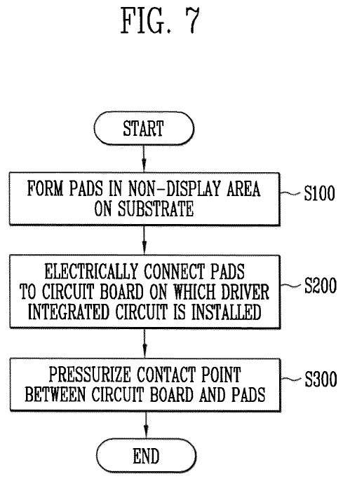

Hereinafter, a method of manufacturing the display device DD will be described with reference to FIG. 7.

FIG. 7 is a flowchart illustrating the method of manufacturing the display device DD according to an embodiment.

The manufacturing method of the display device DD illustrated in FIG. 7 may be a method of manufacturing the display device DD using the pressing apparatus PA of FIGS. 1-3.

Referring to FIG. 7, the method of manufacturing the display device DD may include a step S100 of forming pads in a non-display area on a substrate, and a step S200 of electrically connecting the pads to a circuit board on which a driver integrated circuit is installed.

In an embodiment, the step S100 of forming the pads in the non-display area on the substrate may be performed in the same process as at least one of processes of forming the anode electrode AE, the cathode electrode CE, the first conductive layer MT1, and the second conductive layer MT2 on the substrate SUB.

In some embodiments, various conductive layers and insulating layers on the substrate SUB may be formed based on a general process for manufacturing a semiconductor device. For example, in an embodiment the conductive layers or the insulating layers on the substrate SUB may be formed by a photolithography process, may be etched by various methods, such as wet or dry etching, and may be deposited by a method, such as sputtering or chemical vapor deposition, but are not necessarily limited thereto.

After the step S100 of forming the pads in the non-display area on the substrate, the step S200 of electrically connecting the pads with the circuit board on which the driver integrated circuit is installed may be performed. In some embodiments, the step S200 of electrically connecting the circuit board and the pads may include a step S300 of pressurizing a contact point between the circuit board and the pads PD by using the pressing apparatus PA. As described above, the compression head PH of the pressing apparatus PA maintains the state in which the rotation center axes of the second driving unit DU2 that adjusts the working height (e.g., movement in the third direction D3 in FIGS. 1 to 3) and the third driving unit DU3 (e.g., the first driving shaft DX1 and the second driving shaft DX2) that adjusts the rotation radius aligned with the alignment axis AA, so that the compression accuracy may be maintained even when the pressing apparatus PA is driven for a long time, so that the contact point between the circuit board and the pads PD may be accurately pressed.

In an embodiment, after the step S200 of electrically connecting the circuit board and the pads, the light blocking layer LBP, the color filter layer CFL, and the overcoat layer OC may be disposed, and as a result, the display device DD according to embodiments of the present disclosure may be provided.

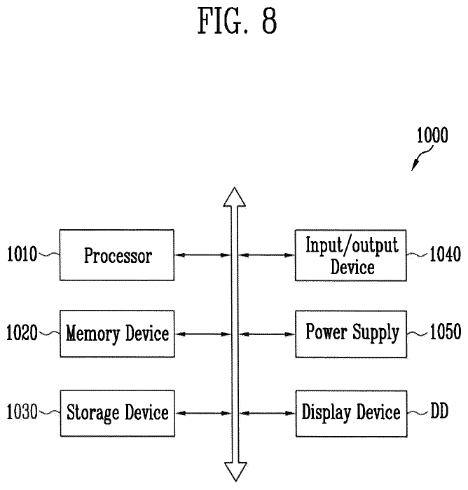

Hereinafter, an electronic device 1000 including the display device DD manufactured according to the above-described manufacturing method will be described with reference to FIGS. 8 to 10.

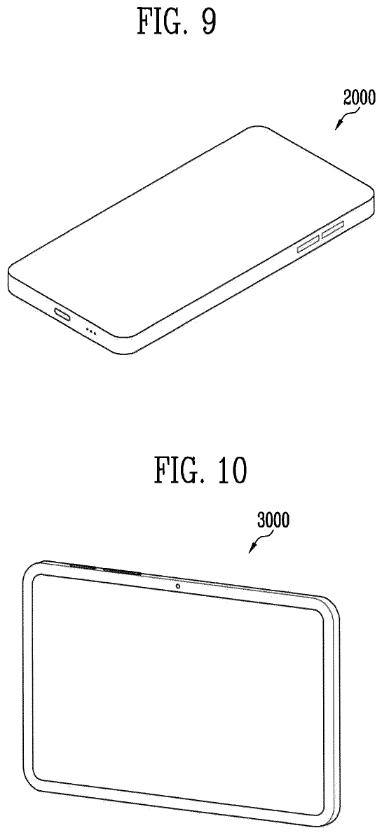

FIG. 8 is a block diagram illustrating an embodiment of the electronic device 1000 including the display device DD of FIG. 9. FIG. 9 is a perspective view illustrating an example of a smartphone that can be implemented using the electronic device 1000 of FIG. 8. FIG. 10 is a perspective view illustrating an example of a tablet computer that can be implemented using the electronic device 1000 of FIG. 8.

Referring to FIG. 9, in an embodiment the electronic device 1000 may include a processor 1010, a memory device 1020, a storage device 1030, an input/output device 1040, a power supply device 1050, and the display device DD.

In some embodiments, as shown in FIG. 9 the electronic device 1000 may be implemented as a smartphone 2000. In some embodiments, as shown in FIG. 10, the electronic device 1000 may be implemented as a tablet computer 3000. However, this mere an example, and the electronic device 1000 is not necessarily limited thereto. For example, the electronic device 1000 may be an electronic device (e.g., computing system) including the display device DD, such as a digital television, a 3D TV, a personal computer (PC), a home electronic device, a laptop computer, a mobile phone, a video phone, a smart pad, a smart watch, a head mounted display device, a personal digital assistant (PDA), a portable multimedia player (PMP), a digital camera, a music player, a portable game console, navigation, or the like. However, the electronic device 1000 may be various other small-sized, medium-sized or large-sized electronic devices.

The processor 1010 may perform various tasks and calculations. In some embodiments, the processor 1010 may include an application processor, a graphics processing unit, a microprocessor, a central processing unit (CPU), and the like. The processor 1010 may be connected to other components of the electronic device 1000 through a bus system. In some embodiments, the bus system may include a Peripheral Component Interconnect (PCI) bus. The processor 1010 may provide a data stream to be displayed on the display device DD.

The memory device 1020 may be provided as a working memory and/or a buffer memory of the electronic device 1000 and/or the processor 1010. In some embodiments, the memory device 1020 may include volatile memory devices, such as dynamic random access memory (DRAM), static random access memory (SRAM), mobile DRAM, and the like.

The storage device 1030 may store data in response to the control of the processor 1010. The storage device 1030 may include a non-volatile storage medium that maintains data even when the electronic device 1000 is powered down. In some embodiments, the storage device 1030 may include a solid state drive (SSD), a hard disk drive (HDD), or the like.

The input/output device 1040 may include user input devices, such as a keyboard, keypad, touchpad, touchscreen, mouse, and the like, and output devices, such as a speaker, printer, or the like.

The power supply device 1050 may supply power necessary for the operation of the electronic device 1000. For example, the power supply device 1050 may be a power management integrated circuit (PMIC). For example, the power supply device 1050 may include a battery.

The display device DD may display an image in response to (e.g., based on) control signals from the processor 1010. The display device DD may be connected to other components of the electronic device 1000 via a bus system and/or other communication links. The display device DD may be the display device DD of FIG. 6. The display device DD may display an image on the pixels PXL, and each of the pixels PXL may be configured as shown in FIG. 5 according to an embodiment.

According to embodiments of the present disclosure, a pressing apparatus with increased pressing accuracy of a compression head, a display device manufactured by the same, and a computing system including the same are provided.

However, effects of embodiments of the present disclosure are not limited to the above-described effects, and various modifications are possible without departing from the spirit and scope of the present disclosure.

Although non-limiting embodiments and applications have been described herein, it is to be understood that different embodiments and modifications may be derived from the above description. Accordingly, the present disclosure is not limited to the described embodiments.

What is claimed is:

1. A pressing apparatus comprising:
a support bracket movable in at least one of a first direction and a second direction intersecting the first direction;
a first housing disposed on an inner side of the support bracket, the first housing is slidable in the second direction;
a first driving unit disposed in the support bracket, the first driving unit providing a driving force to the first housing;
a second housing disposed on an inner side of the first housing, the second housing is slidable in a third direction intersecting the first direction and the second direction;
a second driving unit disposed in the first housing, the second driving unit providing a driving force to the second housing;
a third driving unit disposed in the second housing, the third driving unit generating a rotational force rotating about the third direction; and
a compression head disposed in the third driving unit, the compression head is rotatable by the rotational force of the third driving unit;
wherein the second driving unit and the third driving unit are aligned on an imaginary line extending in the third direction.

2. The pressing apparatus according to claim 1, wherein the first driving unit includes a first driving shaft coupled to the first housing by a ball screw,
wherein the second driving unit includes a second driving shaft coupled to the second housing by a ball screw,
wherein the third driving unit includes a third driving shaft coupled to the compression head, and
wherein the second driving shaft and the third driving shaft are aligned on the imaginary line.

3. The pressing apparatus according to claim 1, wherein the first driving unit is a servo motor.

4. The pressing apparatus according to claim 1, wherein the second driving unit is a servo motor.

5. The pressing apparatus according to claim 1, wherein the third driving unit is a servo motor.

6. The pressing apparatus according to claim 1, further comprising a first guide member disposed between the support bracket and the first housing, the first guide member guiding a sliding of the first housing in the second direction.

7. The pressing apparatus according to claim 6, wherein the first guide member includes:
a 1_1 guide member and a 1_2 guide member located to be symmetrical to each other in the first direction with respect to the imaginary line; and
a 1_3 guide member and a 1_4 guide member located to be spaced apart from the 1_1 guide member and the 1_2 guide member in the third direction, respectively, and located to be symmetrical to each other in the first direction with respect to the imaginary line.

8. The pressing apparatus according to claim 6, wherein the first guide member is a cross roller guide.

9. The pressing apparatus according to claim 6, wherein the first guide member limits the first housing from moving in the first direction and the third direction.

10. The pressing apparatus according to claim 1, further comprising a second guide member disposed between the first housing and the second housing, the second guide member guiding a sliding of the second housing in the third direction.

11. The pressing apparatus according to claim 10, wherein the second guide member includes a 2_1 guide member and a 2_2 guide member located to be symmetrical to each other in the second direction with respect to the imaginary line.

12. The pressing apparatus according to claim 10, wherein the second guide member is an LM guide.

13. The pressing apparatus according to claim 10, wherein the second guide member limits the second housing from moving in the first direction and the second direction.

14. The pressing apparatus according to claim 1, wherein, when the first housing slides in the second direction, the second driving unit and the third driving unit remain aligned on the imaginary line.

15. A method of manufacturing a display device, the method comprising:
forming pads in a non-display area on a substrate; and
electrically connecting the pads and a circuit board having a driver integrated circuit installed thereon,
wherein the electrically connecting of the pads and the circuit board includes pressurizing a contact point between the circuit board and the pads using a pressing apparatus,
wherein the pressing apparatus includes:
a support bracket movable in at least one of a first direction and a second direction intersecting the first direction;
a first housing disposed on an inner side of the support bracket, the first housing is slidable in the second direction;
a first driving unit disposed in the support bracket, the first driving unit providing a driving force to the first housing;
a second housing disposed on an inner side of the first housing, the second housing is slidable in a third direction intersecting the first direction and the second direction;
a second driving unit disposed in the support bracket, the second driving unit providing a driving force to the second housing;
a third driving unit disposed in the support bracket, the third driving unit generating a rotational force rotating about the third direction; and
a compression head rotatable by the rotational force of the third driving unit, and
wherein the second driving unit and the third driving unit are aligned on an imaginary line extending in the third direction.

16. An electronic device comprising:
a processor;
pixels; and
a display device displaying an image in the pixels in response to control signals from the processor,
wherein the display device is manufactured according to the manufacturing method of claim 15.
